(19) United States
(12) Patent Application Publication
(10) Pub. No.: US 2019/0353519 A1
(43) Pub. Date: Nov. 21, 2019

(54) LIGHT EMITTING STRUCTURES AND SYSTEMS ON THE BASIS OF GROUP IV MATERIAL(S) FOR THE ULTRAVIOLET AND VISIBLE SPECTRAL RANGES

(71) Applicant: Ventsislav Metodiev Lavchiev, Gallneukirchen (AT)

(72) Inventor: Ventsislav Metodiev Lavchiev, Gallneukirchen (AT)

(21) Appl. No.: 16/531,606

(22) Filed: Aug. 5, 2019

Related U.S. Application Data
(62) Division of application No. 15/169,921, filed on Jun. 1, 2016, now abandoned.

(30) Foreign Application Priority Data
May 3, 2016 (GB) GB1607684.6

(51) Int. Cl. G01J 1/42; H01L 33/34; G02B 1/02; G02B 5/00

(52) U.S. Cl. CPC G01J 1/42; H01L 33/34; H01L 33/343; G01J 2001/4247; G01J 1/429; G02B 5/008; G02B 1/02

(57) ABSTRACT

Material structures, systems and devices are disclosed. The material structures are active materials, which are able to emit UV/visible light under excitation by bias, by light beam or by electron beam. The input unit is a source of voltage/current or a source of light or a source of electron beam. The active unit is a material structure containing one or more layers of the described materials. The system may include a passive unit such as a ring resonator, a waveguide, coupler, grating or else. Additional units such as a control unit, readout unit or else may be also incorporated.

The distinguished characteristic of the present invention is that the UV or visible emission from the described structures cannot happen without the presence of at least one of the following quasi-particles: surface plasmons, surface plasmon polaritons, bulk plasmons and/or bulk plasmon polaritons. These quasi-particles assist the UV and the visible light emission.

### FIELD

The present disclosure generally relates to emission of light by highly crystalline materials, structures and devices fabricated and designed in a specific manner allowing for such light emission. The light emission, taking place in the ultraviolet UV and visible spectral ranges, is linked to bulk and surface plasmon polaritons in the materials and their interfaces, to the intraband and interband transitions of the electrons and holes in the valence band and conduction band, to the coupling between the surface plasmon polaritons and the particles generated in the intraband and interband transitions. The light emission is further linked to the oxygen related states on the Si and Ge interfaces with their oxides. The light emission, however, cannot happen without the presence of at least one of the following quasi-particles: surface plasmons, surface plasmon polaritons, bulk plasmons and/or bulk plasmon polaritons.

### BACKGROUND

Light emitters are material, structures or devices capable of emission of light when voltage or light of another wavelength or electron beam is applied to them. One type of light emitters is the emitters of visible light such as broadband lamps sources (in terms of spectral width of the emission). Another type of light emitter emits narrow spectral light such as light emitting diodes (LED), organic LED (OLED). Another type of light source is the laser, which is an emitter of coherent, narrow spectral light. Yet another type of emitters can emit light in ultra-violet or infrared spectral ranges.

The light emitters have a broad range of applications—for lighting, in TV screens, automobiles, data transmission, computers, radars, decoration, military, entertaining industry, night vision, sensor technologies, traffic control, in manufacturing or control in the manufacturing processes.

All existing to date light emitters are characterized by at least one of the following features—high power consumption, relatively high price, requirement of special technology for fabrication, use of relatively expensive materials for fabrication or non-compatibility to the silicon (Si)-based technology.

However, a light source based on a group-IV material—silicon (Si), germanium (Ge), tin (Sn), lead (Pb), carbon (C, for instance silicon carbide SiC), erbium (Er) or a combination of them—would bring enormous advantages for the Si-based industry and related industries.

The present invention is an efficient light emitter based on Si or Ge or combination of them or combination of these materials with their oxides or combination of them with antimony (Sb) or any doping.

### BRIEF DESCRIPTION OF THE DRAWINGS

The following is a brief description of the figures wherein the definitions “material structure” and “structure” are equal. All the materials are to be understood as highly crystalline or monocrystalline.

FIG. 1 is a diagram, illustrating a material structure composed of simply bulk monocrystalline Si.

FIG. 2A is a diagram illustrating a two-layer structure Ge/Si.

FIG. 2B is a diagram illustrating a two-layer structure SiO/Si.

FIG. 2C is a diagram illustrating a two-layer structure SiO₂/Si.

FIG. 3A is a diagram illustrating a two-layer structure Ge/SiO_{0.5}.

FIG. 3B is a diagram illustrating a two-layer structure Si/SiO_{0.5}.

FIG. 4A is a diagram illustrating a two-layer structure Ge/SiO.

FIG. 4B is a illustrating a two-layer structure Si/SiO.

FIG. 5A is a diagram illustrating a two-layer structure Ge/SiO₂.

FIG. 5B is a diagram illustrating a two-layer structure Si/SiO₂.

FIG. 6A is a diagram illustrating a two-layer structure GeO/Ge.

FIG. 6B is a diagram illustrating a two-layer structure GeO₂/Ge.

FIG. 7 is a diagram of a multilayer structure consisting of any combination of the above mentioned materials.

FIG. 8A is a diagram of a device based on one or more of the above mentioned materials. The diagram illustrates a device capable of light emission in UV, violet or visible spectral range when excitation of the structure by electrical mean i.e. bias is applied.

FIG. 8B is a diagram of a device based on one or more of the above mentioned materials. The diagram illustrates a device capable of light emission in UV, violet or visible spectral range when excitation of the structure by optical mean i.e. by light is applied.

FIG. 8C is a diagram of a device based on one or more of the above mentioned materials. The diagram illustrates a device capable of light emission in UV, violet or visible spectral range when excitation of the structure by electron beam is applied.

Optical excitation or excitation by bias can be applied to a multilayer structure (FIG. 7) in the similar way as in FIG. 8A or FIG. 8B.

FIG. 9 is a diagram illustrating a device, in which one of the above mentioned structures is placed in a resonator or a cavity for light amplification.

### DETAILED DESCRIPTION

The present invention will now be described with reference to the attached drawing figures, wherein like reference numerals are used to refer to like elements throughout, and wherein the illustrated structures and devices are not necessarily drawn to scale.

The light emitters in the present invention are based on a single-layer or bi-layer or a multi-layer material structure. The materials are monocrystalline, where applicable. The structure emits UV or visible light when excited electrically, optically or by an electron beam. The size, shape and composition of the materials forming the structure(s) can be varied or adjusted to form different devices, properties or features.

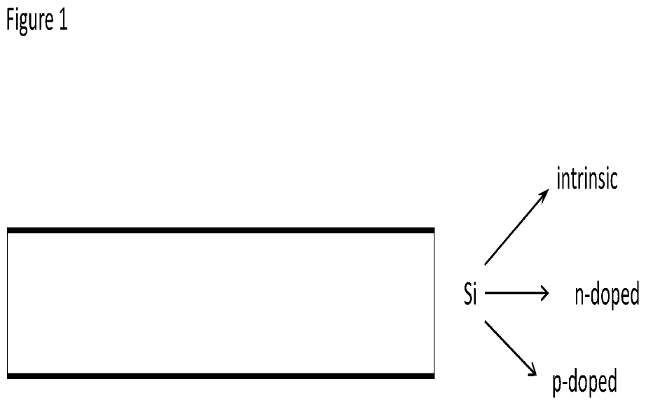

FIG. 1 is a diagram illustrating a structure from bulk monocrystalline Si. The Si can be intrinsic or doped. The structure is capable of UV/visible light emission under electrical or optical excitation or under excitation by an electron beam.

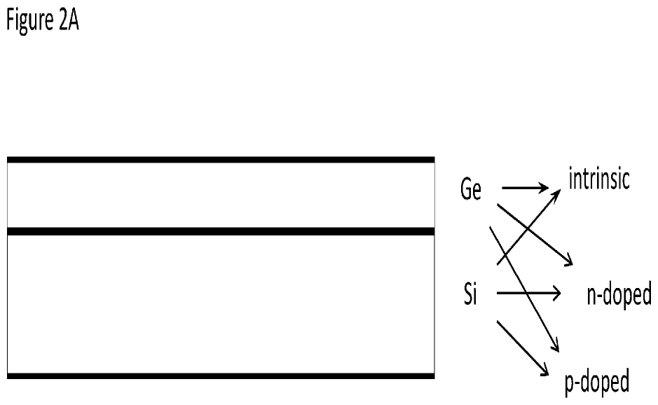

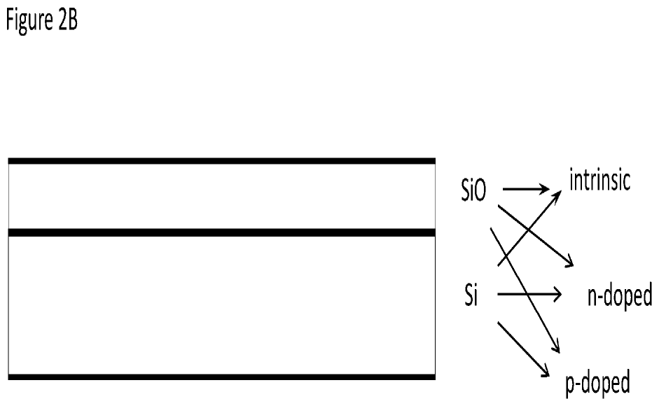

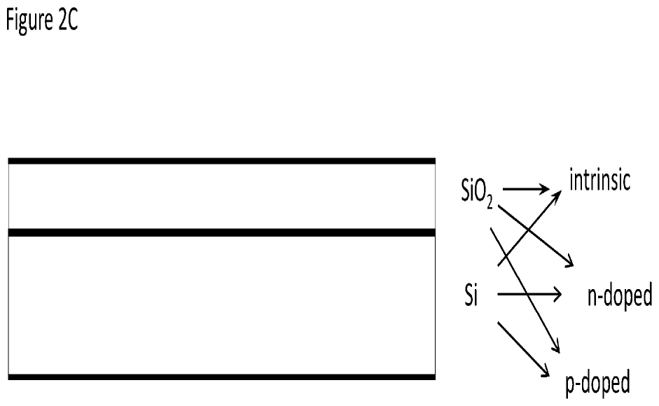

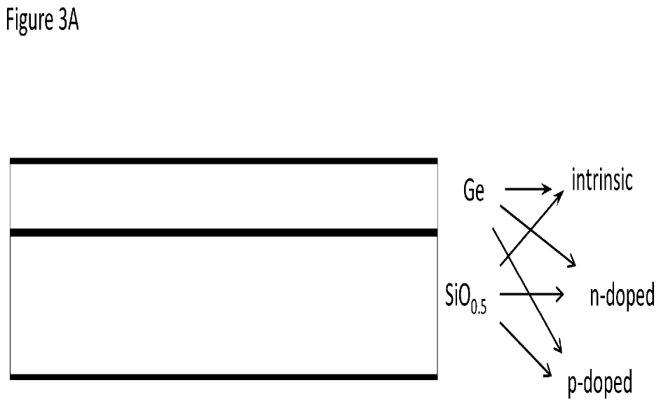

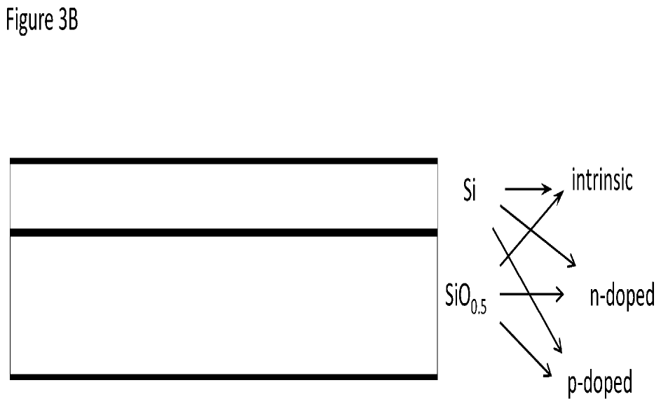

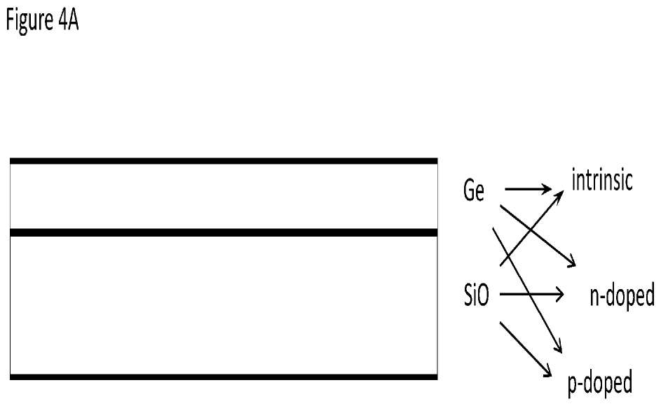

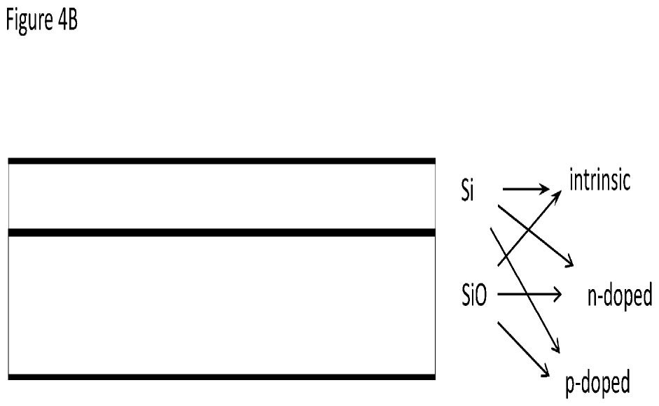

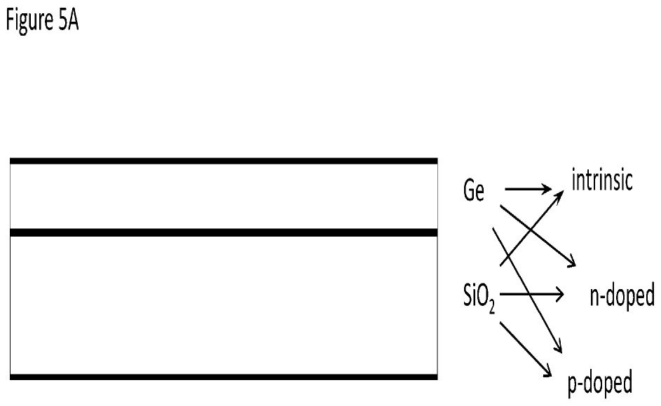

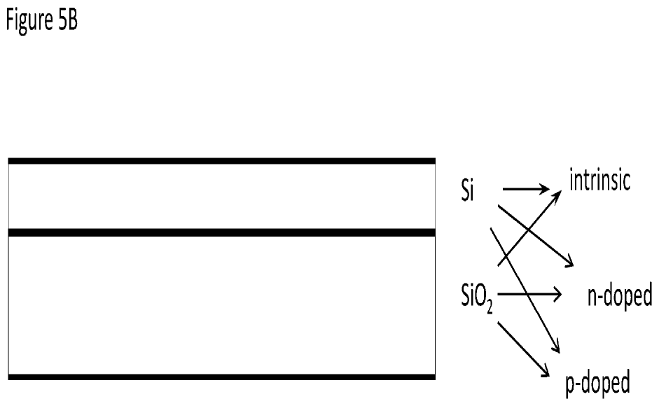

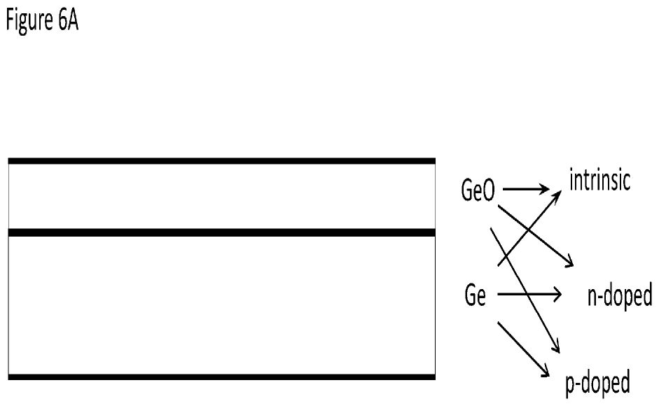

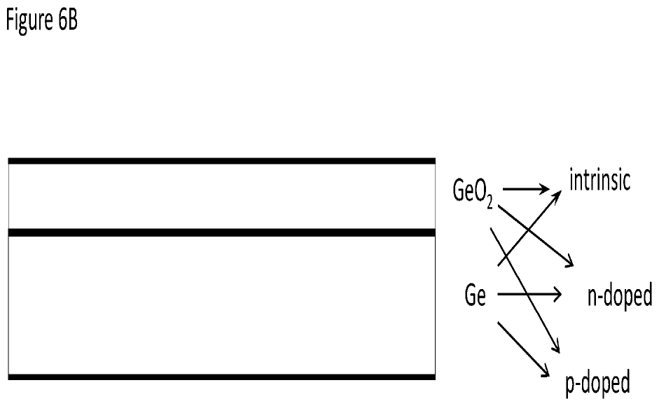

The bi-layer structures illustrated in FIG. 2A, FIG. 2B, FIG. 2C, FIG. 3A, FIG. 3B, FIG. 4A, FIG. 4B, FIG. 5A, FIG. 5B, FIG. 6A and FIG. 6B are capable of UV and/or visible light emission under electrical excitation (electroluminescence) or optical excitation (photoluminescence) or under excitation by an electron beam (cathodo-luminescence). The structures are composed of monocrystalline Si (undoped or doped), monocrystalline Ge (undoped or doped) and their oxides in combinations as depicted in the figures.

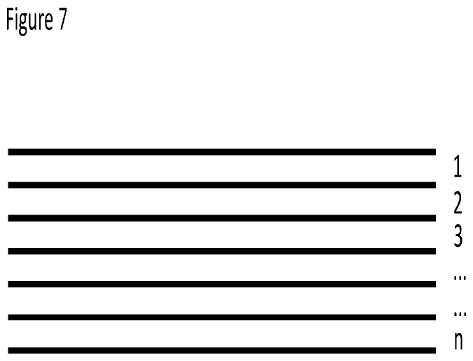

FIG. 7 is a diagram illustrating a multilayer structure composed of any combination of the following materials—Si, Ge, SiO, SiO₂, SiO_{0.5}, SiOₓ, where 0≤x≤1. Any layer of the multi-layer structure can be intrinsic or doped.

The doping can be p-type or n-type such as B (boron), Sb (antimony), P (phosphorous) or else. The doping is important for light emission even in the case of excitation of the structure(s) by optical beam or by electron beam. The doping changes the dielectric constant of the material, which in turn changes the spectral position of the plasmon and the plasmon polariton.

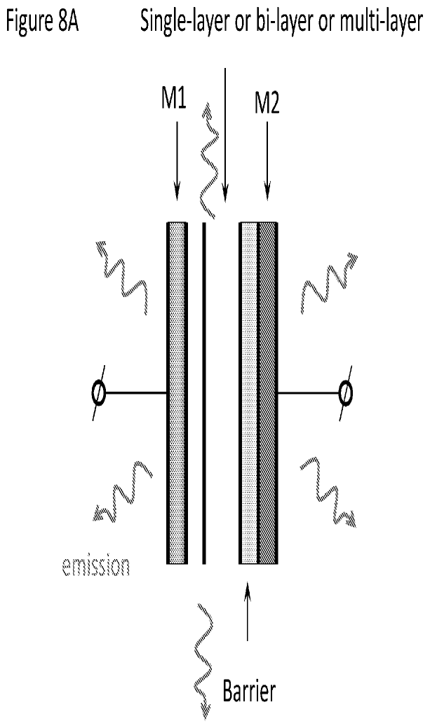

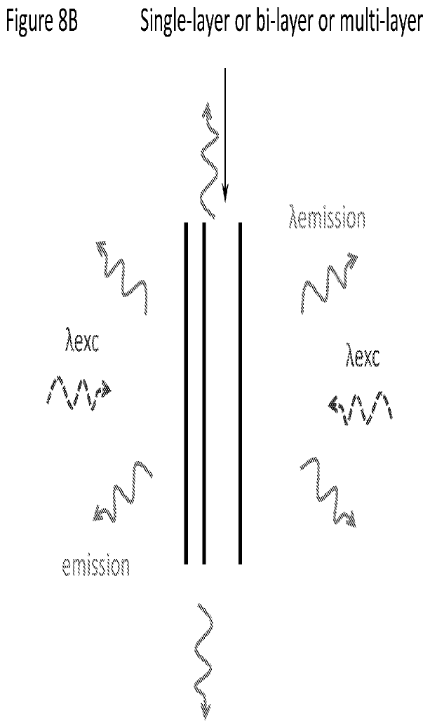

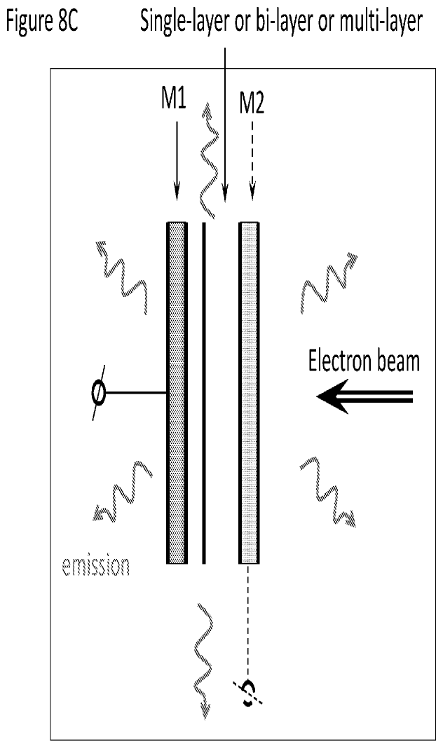

FIG. 8A is a diagram illustrating electrical excitation of a single-layer or bi-layer or multi-layer structure. The electrical excitation is done by means of application of bias. Electrode layers are deposited on both sides of the structure. The bias is applied to the electrodes. A barrier layer can be deposited between the electrode layer and the light emitting layer. In one example, the structure under electrical excitations is composed of the following layers ordered in a strict order: Cs (cesium) or Au (gold) electrode layer/emitting material/LaGdO₃ barrier layer/LaB₆ electrode layer. In another example, the structure under electrical excitations is composed of the following layers ordered in a strict order: Cs (cesium) or Au (gold) electrode layer/emitting material/LaBaO₃ barrier layer/LaB₆ electrode layer. The metals Cs and Au are selected due to their low work functions necessary in the electric excitation. In another example, other materials can be used as electrode layers and barrier layer. Unlike the conventional p-n, p-i-n or other junctions known to date, the presented structures in FIG. 7A generates light also by undoped materials and only when surface or/and bulk plasmons or plasmon polaritons are present (generated) in the material(s).

The generation of the surface plasmons, surface plasmon polaritons, bulk plasmons and/or bulk plasmon polaritons occurs simultaneously with the excitation bias/beam.

FIG. 8B is a sketch showing excitation of the structure by optical mean. In one example, the excitation source is a light source of a smaller wavelength as comparison to the wavelength of the emission from the structure (λ_{excitation}<λₑₘᵢₛₛᵢₒₙ). In another example, the excitation source is a broad band light source.

FIG. 8C is a sketch showing excitation of the structure by an electron beam. The structure is capable of light emission of UV and visible light under bombardment of the material (structure) by an electron beam. An electrode layer/structure can be deposited on the back surface or/and the front surface of the structure required for this type of excitation. In another example, the material structure is placed on a metal support playing the role of the electrode. Yet in another example, the electrode may be placed away from the material structure. The purpose of the electrode is to accelerate the electron beam (emitted from a cathode electrode) toward the material structure.

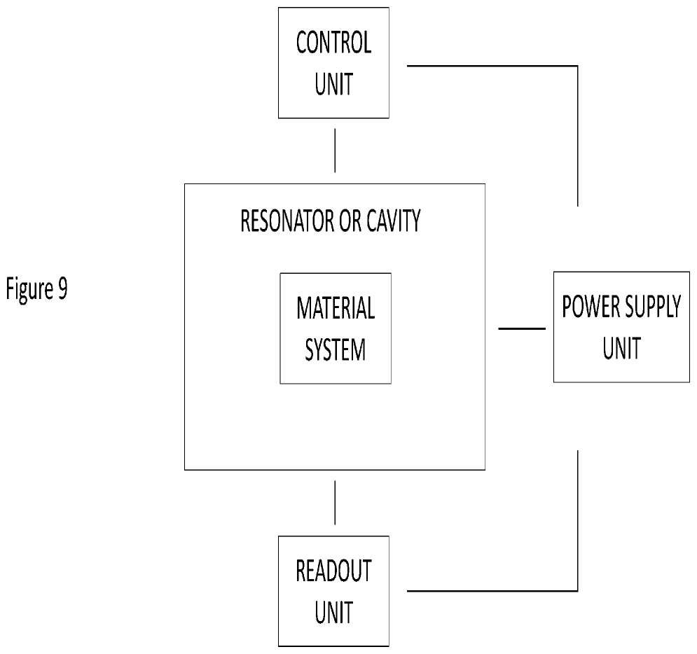

FIG. 9 illustrates a device, wherein the emitting structure named “material system” is placed in a resonator or a cavity. The purpose of the resonator/the cavity is to amplify the light emitted from the structure. The device also includes one or more additional units such as a control unit, a power supply unit and a readout unit. Additional unit may be the excitation source.

The material system in FIG. 8C and FIG. 9 may be placed in vacuum environment.

1-8. (canceled)

9. A method of generating plasmons or polaritons, or both, comprising:
providing a material structure, comprising:
a first layer, comprising:
a top surface; and
a bottom surface;
an interface layer, comprising:
a top surface; and
a bottom surface;
a second layer, comprising:
a top surface; and
a bottom surface;
wherein the bottom surface of the interface layer is directly attached to the top surface of the first layer;
wherein the bottom surface of the second layer is directly attached to the top surface of the interface layer;
wherein the first layer comprises silicon, silicon oxide, germanium, or germanium oxide;
wherein the interface layer comprises:
a selected phase of oxide SiOx, where 0≤x≤1; or
a selected phase of oxide GeOy, where 0≤y≤1;
wherein the second layer comprises silicon, silicon oxide, germanium, or germanium oxide;
wherein a material of the first layer is different from a material of the interface layer;
wherein the material of the interface layer is different from a material of the second layer; and
wherein the material of the first layer is different from the material of the second layer; and
exciting the material structure with an excitation source, thereby causing the material structure to emit light in the ultra-violet (UV) spectral range or the visible light (VIS) spectral range.

10. The method of claim 9, wherein the material structure further comprises:
a top electrode layer, comprising:
a top surface; and
a bottom surface;
a barrier layer, comprising:
a top surface; and
a bottom surface; and
a bottom electrode layer, comprising:
a top surface; and
a bottom surface;
wherein the bottom surface of the top electrode layer is directly attached to the top surface of the second layer;
wherein the top surface of the barrier layer is directly attached to the bottom surface of the first layer; and
wherein the top surface of the bottom electrode layer is directly attached to the bottom surface of the barrier layer.

11. The method of claim 10, wherein exciting the material structure with an excitation source comprises applying a bias voltage across the material structure by applying a first potential to the top electrode layer, and applying a second, different potential to the bottom electrode layer.

12. The method of claim 10,
wherein the top electrode layer comprises cesium or gold;
wherein the barrier layer comprises LaBaO₃; and
wherein the bottom electrode layer comprises LaB₆.

13. The method of claim 9, wherein exciting the material structure with an excitation source comprises directing an electron beam at the material structure.

14. The method of claim 9, wherein exciting the material structure with an excitation source comprise directing an optical beam at the material structure.
